(19) United States
(12) Patent Application Publication
(10) Pub. No.: US 2008/0224545 A1
(43) Pub. Date: Sep. 18, 2008

(54) PULSE GENERATING DEVICE AND METHOD

(75) Inventors: Wan-Kun Chang, Chutung (TW); Kuei-Lu Liu, Chutung (TW); Jui-Kuan Lin, Chutung (TW); Yung-Ming Kao, Chutung (TW); Shih-Chang Liang, Chutung (TW); Chia-Sheng Chiang, Chutung (TW)

Correspondence Address: Allen, Dyer, Doppelt Milbrath & Gilchrist, P.A., 1401 Citrus Center, 255 South Orange Avenue, Orlando, FL, 32802-3791, US

(73) Assignee: Industrial Technology Research Institute, Chutung (TW)

(21) Appl. No.: 11/839,873

(22) Filed: Aug. 16, 2007

(30) Foreign Application Priority Data
Mar. 14, 2007 (TW) 096108839

(51) Int. Cl. H03K 3/00

(52) U.S. Cl. 307/106; 327/291

(57) ABSTRACT

A pulse generating device and method are provided. The pulse generating device includes a control device, a first knob, and a second knob. The control device is configured to receive a pulse signal and generate a pulse command. After being actuated, the first knob provides a single pulse of the pulse signal to the control device for triggering the control device to generate a single pulse command. The second knob provides the pulse signal to the control device in a frequency corresponding to a twisted angle of the second knob so as to trigger the control device to repeatedly generate the pulse command.

### FIELD OF THE INVENTION

The present invention relates to a pulse generating device and method. More particularly, the pulse generating device and method are a manual pulse generating device and method for moving a working machine.

### BACKGROUND OF THE INVENTION

The pulse generating device has been an indispensable accessory to machine tools and measuring machines for a long time. The pulse generating device generates pulse commands for driving a motor and achieving the purpose of moving a working machine by twisting a knob and modulating an axial direction determining switch and a multiplication parameter determining switch.

Please refer to FIG. 1, which is a diagram showing the panel of a pulse generating device in the prior art. As shown, the pulse generating device 18 comprises a knob 19, an axial direction determining knob 6 and a multiplication parameter determining knob 7.

Please refer to FIG. 2, which is a block diagram showing the operation principle of a pulse generating device in the prior art. As shown, when a user twists the knob 19, a pulse command will be generated. Twisting each scale of the knob 19 will cause the pulse generating device 18 to output a pulse command 15. The knob 19 comprises a grating pulse generating circuit (not shown) for generating the pulse command 15. The output rate, which changes the moving rate of a working machine, of the pulse command 15 depends on the twisted rate of the knob 19. According to the setting of the axial direction determining knob 6 and the multiplication parameter determining knob 7, the traditional pulse generating device 18 will respectively generate pulse signals of a corresponding axial direction command 16 and a corresponding multiplication parameter command 17 to the working machine 10 for moving the working machine along different axial directions and at different multiplication rates.

However, if the moving distance of the working machine is very long, the operator has to continuously twist the knob 19 for several ten's of seconds or even for several minutes. The operating process is inconvenient and inefficient, which males the operator's wrist tired, and the twisting rate controlled by the operator is unstable, which makes the output rate of the pulse command 15 unstable as well, thereby deteriorating the quality of the processed product. Furthermore, problems of over-cutting, over-torsion and tool broken are easily generated during the manual operating process. For example, when fine tuning the move of the working machine, the operator needs to twist the knob 19 carefully for one scale for generating a pulse command 15, but the problem of over-cutting of the product is often happened because of the incautious mistake that two or three scales are twisted.

Please refer to FIG. 3, which is a diagram showing the structure of a force feedback knob device in the Taiwan Application No. 089222980. As shown, the force feedback system 20 comprises a force feedback unit 22 and an actuating brake device 21. The force feedback system 20 detects a force loading state of a servomotor and provides the state feedback to the actuating brake device 21, which will generate braking force to make the user feel an increase of the cutting force. Although there is a force feedback system 20 in the prior art, it only makes the user feel an increase of the cutting force via the actuating brake device 21, where the problems of tired wrist, inefficient working, over-cutting, over-torsion and tool broken caused by long-distance cutting are still unsolved. Moreover, when fine tuning the output of a pulse command 15, the mistake of over-cutting is easily happened as well.

Therefore, because of the defects in the prior art, the inventors provide a pulse generating device and method to effectively overcome the demerits existing in the prior art.

### SUMMARY OF THE INVENTION

It is an aspect of the present invention to provide a pulse generating device and method for solving problems of tired wrist for lone cutting distance, over-cutting, over-torsion and tool broken during the operation of the pulse generating device.

In accordance with the aspect of the present invention, a pulse generating device is provided. The pulse generating device comprises a control device, which receives a pulse signal and generates a pulse command, a first knob, which provides a single pulse of the pulse signal to the control device after being actuated for triggering the control device to generate a single pulse command, and a second knob, which provides the pulse signal to the control device in a frequency corresponding to a twisted angle of the second knob so as to trigger the control device to repeatedly generate the pulse command.

Preferably, the pulse generating device further comprises a torsion limiting knob for setting and providing a torsion limiting value to the control device, which is configured to receive a torsion value from a driver coupled to the pulse generating device and to compare the torsion value with the torsion limiting value. If the torsion value is smaller than the torsion limiting value and the first knob is actuated, the control device outputs the single pulse command; if the torsion value is smaller than the torsion limiting value and the second knob is actuated, the control device outputs the repeatedly generated pulse command in the corresponding frequency. If the torsion value is larger than or is equal to the torsion limiting value and the first knob is actuated, the control device will not output the single pulse command. If the torsion value is larger than or is equal to the torsion limiting value and the second knob is actuated, the control device will not output the repeatedly generated pulse command.

Preferably, the pulse generating device further comprises a torsion limiting knob for setting and providing a torsion limiting value to the control device. If the torsion value is smaller than the torsion limiting value and the second knob is actuated, the control device outputs the repeatedly generated pulse command in the corresponding frequency. If the torsion value is larger than or is equal to the torsion limiting value, the control device outputs the repeatedly generated pulse command in a frequency smaller than the corresponding frequency.

Preferably, the pulse generating device, which has a slope limiting value, further comprises a torsion limiting knob for setting and providing a torsion limiting value with the control device. If the torsion value is smaller than the torsion limiting value and the second knob is actuated, the control device outputs the repeatedly generated pulse command in the corresponding frequency. If the torsion value is larger than or is equal to the torsion limiting value and a slope of a torsion value-time curve of a device coupled to the pulse generating device is smaller than the slope limiting value, the control device outputs the repeatedly generated pulse command in a frequency slower than the corresponding frequency. If the torsion value is larger than or is equal to the torsion limiting value and the slope of the torsion value-time curve is larger than or is equal to the slope limiting value, the control device will not provide the pulse commands.

Preferably, the pulse generating device further comprises an axial direction determining unit determining an axial direction and providing an axial direction command. The pulse command and the axial direction command are provided to a working machine for moving the working machine along the axial direction.

Preferably, the pulse generating device further comprises a multiplication parameter determining unit determining a multiplication parameter for a frequency of the pulse command and providing a multiplication parameter command to a working machine for moving the working machine at a specific multiplication rate.

Preferably, the first knob comprises a photoelectric switch, which is triggered only one time after the first knob is actuated.

Preferably, the second knob has a variable resistance varying with the twisted angle for changing the corresponding frequency accordingly.

In accordance with the aspect of the present invention, a pulse generating method for a pulse generating device is provided. The pulse generating method for the pulse generating device, wherein the pulse generating device comprises a control device receiving a pulse signal and generating a pulse command and a knob device comprising a first knob and a second knob, comprises steps of: (a) providing a single pulse of the pulse signal generated by manually actuating the first knob to the control device for generating a single pulse command; or (b) repeatedly providing the pulse signal by manually actuating the second knob to the control device for repeatedly generating the pulse command.

Preferably, the pulse generating method for the pulse generating device, wherein the pulse generating device further comprises a torsion limiting knob and the control device is further configured to receive a torsion value, further comprises steps of: (a) setting a torsion limiting value via the torsion limiting knob and providing the torsion limiting value to the control device; and (b) comparing the torsion value with the torsion limiting value. If the torsion value is smaller than the torsion limiting value and the first knob is actuated, the control device outputs the pulse command. If the torsion value is larger than or is equal to the torsion limiting value and the first knob is actuated, the control device will not output the pulse command.

Preferably, the pulse generating method for the pulse generating device, wherein the pulse generating device further comprises a torsion limiting knob and the control device is further configured to receive a torsion value, further comprises the steps of: (a) setting a torsion limiting value via the torsion limiting knob and providing the torsion limiting value to the control device; and (b) comparing the torsion value with the torsion limiting value. If the torsion value is smaller than the torsion limiting value and the second knob is actuated, the control device repeatedly provides the pulse command in a frequency of receiving the pulse signal. If the torsion value is larger than or is equal to the torsion limiting value and the second knob is actuated, the control device will not output the pulse command.

Preferably, the pulse generating method for the pulse generating device, wherein the pulse generating device further comprises a torsion limiting knob and the control device is further configured to receive a torsion value, further comprises the steps of: (a) setting a torsion limiting value via the torsion limiting knob and providing the torsion limiting value to the control device; and (b) comparing the torsion value with the torsion limiting value. If the torsion value is smaller than the torsion limiting value and the second knob is actuated, the control device repeatedly provides the pulse command in a first frequency of receiving the pulse signal. If the torsion value is larger than or is equal to the torsion limiting value and the second knob is actuated, the control device repeatedly provides the pulse command in a second frequency smaller than the first frequency of receiving the pulse signal.

Preferably, the pulse generating method for the pulse generating device, wherein the pulse generating device further comprises a slope limiting value and a torsion limiting knob and the control device is further configured to receive a torsion value, further comprises the steps of: (a) setting a torsion limiting value via the torsion limiting knob and providing the torsion limiting value to the control device; and (b) comparing the torsion value with the torsion limiting value, wherein: if the torsion value is smaller than the torsion limiting value and the second knob is actuated, the control device repeatedly provides the pulse command in a first frequency of receiving the pulse signal. If the torsion value is larger than or is equal to the torsion limiting value and the slope of a torsion value-time curve is smaller than the slope limiting value, the control device repeatedly provides the single pulse command in a second frequency smaller than the first frequency of receiving the pulse signals. If the torsion value is larger than or is equal to the torsion limiting value and the slope of the torsion value-time curve is larger than or is equal to the slope limiting value, the control device will not output the pulse command.

In accordance with the aspect of the present invention, a pulse generating device is provided. The pulse generating device comprises a knob providing a pulse signal, a control module receiving the pulse signal and generating a pulse command, and a torsion limiting knob setting a torsion limiting value and providing the torsion limiting value to the control module. The control module compares the torsion limiting value with a received torsion value, wherein: if the torsion value is smaller than the torsion limiting value, the control module outputs the pulse command; and if the torsion value is larger than or is equal to the torsion limiting value, the control module performs a specific scheme.

Preferably, the specific scheme is one of taking no action and repeatedly providing the pulse command in a first frequency smaller than a second frequency of receiving the pulse signal.

Preferably, the control module has a slope limiting value, and the specific scheme is one of that the control module repeatedly provides the pulse command in a first frequency smaller than a second frequency of receiving the pulse signal while a slope of a torsion value-time curve is smaller than the slope limiting value, and that the control module does not output the pulse command while the slope of the torsion value-time curve is larger than or is equal to the slope limiting value.

In accordance with the aspect of the present invention, a pulse generating method is provided. The pulse generating method for a pulse generating device, wherein the pulse generating device comprises a control module, a torsion limiting knob and a pulse signal providing knob providing a pulse signal to the control module, comprises steps of: (a) setting a torsion limiting value via the torsion limiting knob and providing the torsion limiting value to the control module; and (b) comparing a torsion value with the torsion limiting value, wherein: if the torsion value is smaller than the torsion limiting value, the control module generates a pulse command; and if the torsion value is larger than or is equal to the torsion limiting value, the control module performs a specific scheme.

Preferably, the specific scheme is one of taking no action and repeatedly providing the pulse command by the control module in a first frequency smaller than a second frequency of receiving the pulse signal.

Preferably, the control module has a slope limiting value, and the specific scheme is one of that the control module repeatedly provides the pulse command in a first frequency smaller than a second frequency of receiving the pulse signal while a slope of a torsion value-time curve is smaller than the slope limiting value, and that the control module does not output the pulse command while the slope of the torsion value-time curve is larger than or is equal to the slope limiting value.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a diagram showing the panel of a pulse generating device in the prior art;

FIG. 2 is a block diagram showing the operation principle of a pulse generating device in the prior art;

FIG. 3 is a diagram showing the structure of a force feedback knob device in the prior art;

FIG. 4A is a diagram showing the back of the panel of a pulse generating device according to a preferred embodiment of the present invention;

FIG. 4B is a diagram showing the face of the panel of a pulse generating device according to a preferred embodiment of the present invention;

FIG. 5A1 is a side view of the knob in FIG. 4B;

FIG. 5A2 shows the position of the first knob when not twisted;

FIG. 5A3 shows the position of the first knob when twisted leftward;

FIG. 5A4 shows the position of the first knob when twisted rightward;

FIG. 5B is another side view of the knob in FIG. 4B;

FIG. 5C1 is a further side view of the knob in FIG. 4B;

FIG. 5C2 is a top view of the second knob;

FIG. 6 is a diagram showing the structure of the pulse generating device according to a preferred embodiment of the present invention;

FIG. 7 is a diagram showing the first situation of the repeated pulse signal; and

FIG. 8 is a diagram showing the second situation of the repeated pulse signal.

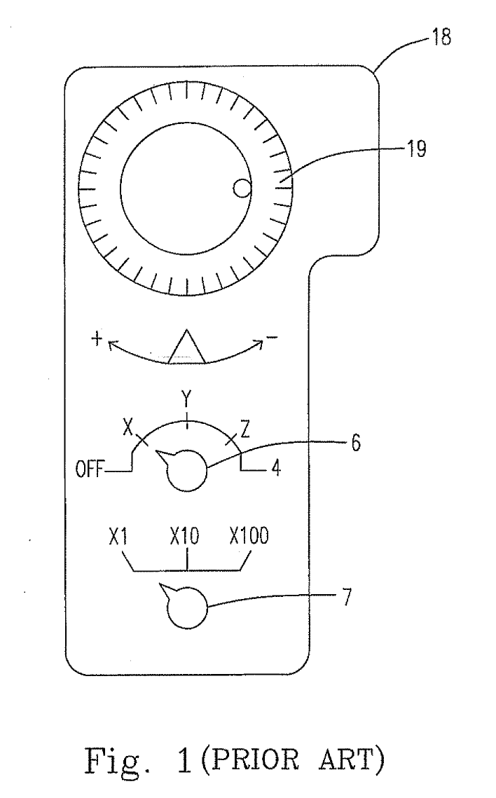

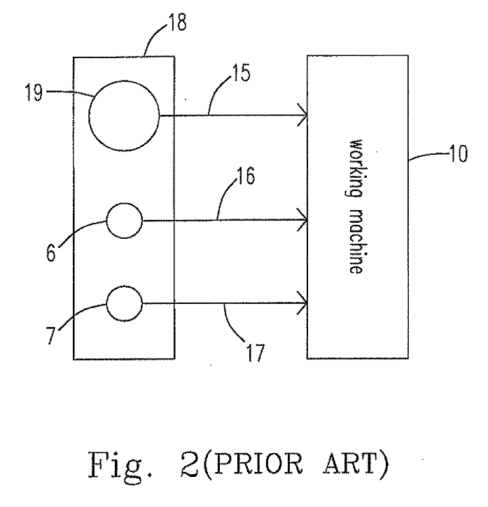

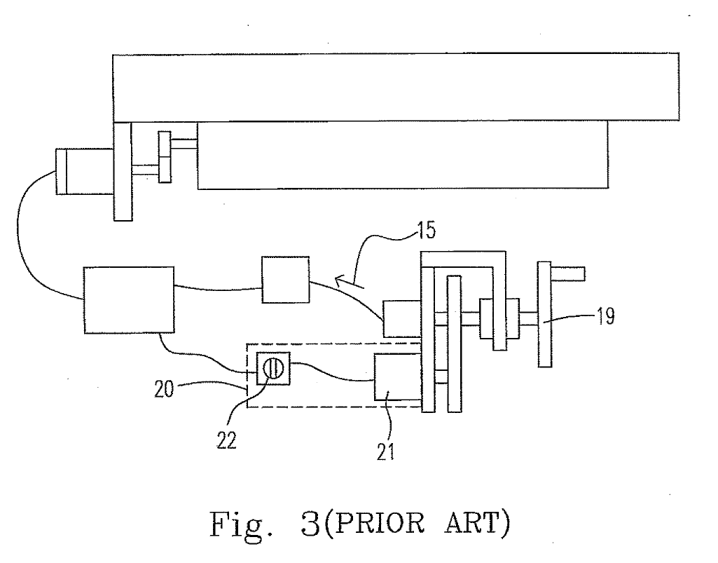

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

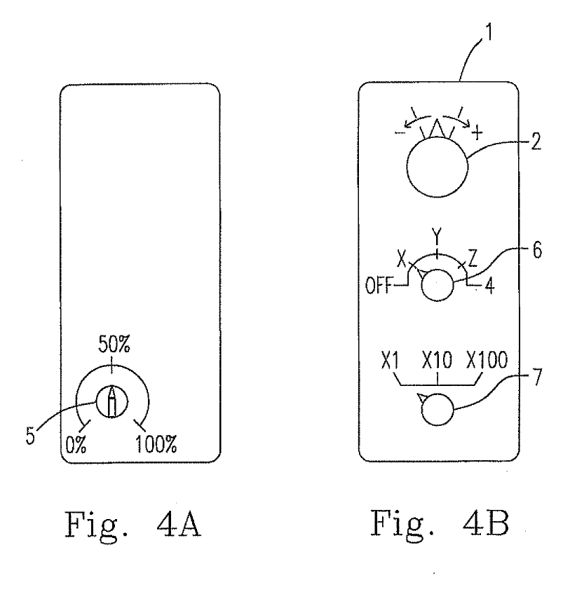

Please refer to FIG. 4A, which is a diagram showing the back of the panel of a pulse generating device according to a preferred embodiment of the present invention, wherein the pulse generating device 1 comprises a torsion limiting knob 5.

Please refer to FIG. 4B, which is a diagram showing the face of the panel of a pulse generating device according to a preferred embodiment of the present invention, wherein the pulse generating device 1 comprises a knob 2, an axial direction determining knob 6 and a multiplication parameter determining knob 7. The knob 2 is a switch structurally having two layers.

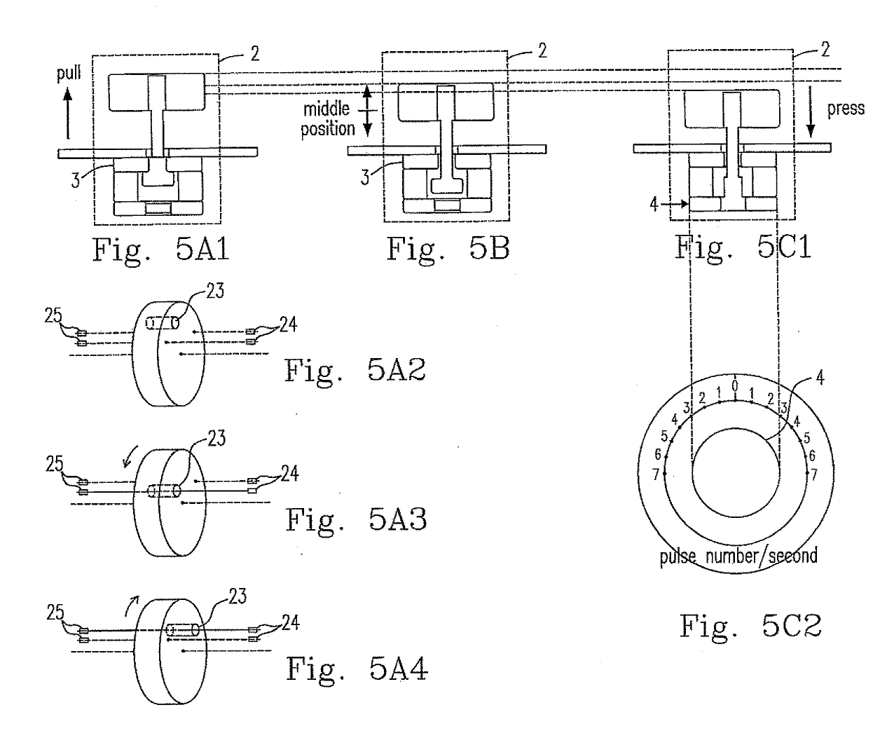

Please refer to FIG. 5A1, which is a side view of the knob in FIG. 4B. If the knob 2 is pulled up to the end and locks a first knob 3 in the upper layer, then the first knob 3, which is a photoelectric switch, can be twisted thereby.

Please refer to FIG. 5A2, which shows the position of the first knob when not twisted. The first knob 3 is a photoelectric switch and has a light hole 23, a light source 24 and a light detector 25. The light hole 23 is in the middle position when no force is applied to the first knob 3.

Please refer to FIG. 5A3, which shows the position of the first knob when twisted leftward. When the fist knob 3 is twisted leftward to the end, the light radiated from the light source 24 will pass through the light hole 23 and be detected by the light detector 25, thereby triggering the first knob 3. The first knob 3 is a regressive knob, which will be back automatically to the middle position while the twisting force disappears (as shown in FIG. 5A2).

Please refer to FIG. 5A4, which shows the position of the first knob when twisted rightward. When the first knob 3 is twisted rightward to the end, the light radiated from the light source 24 will pass through the light hole 23 and be detected by the light detector 25, thereby triggering the first knob 3. The first knob 3 is a regressive knob, which will be back automatically to the middle position while the twisting force disappears (as shown in FIG. 5A2).

Please refer to FIG. 5B, which shows another side view of the knob in FIG. 4B. When the knob 2 is pressed down to the middle position, it will be separated from the first knob 3 and the first knob 3 cannot be twisted thereby.

Please refer to FIG. 5C1, which is a further side view of the knob in FIG. 4B. When the knob 2 is pressed down to the end, it will lock the second knob 4 in the lower layer and the second knob 4 can be twisted thereby.

Please refer to FIG. 5C2, which is a top view of the second knob. As shown, the second knob 4 maintains in the middle position when no force is applied thereto, and it can be twisted leftward or rightward to a specific angle. The second knob 4 has a variable resistance varying with the twisted angle of the second knob 4 for changing the corresponding frequency accordingly.

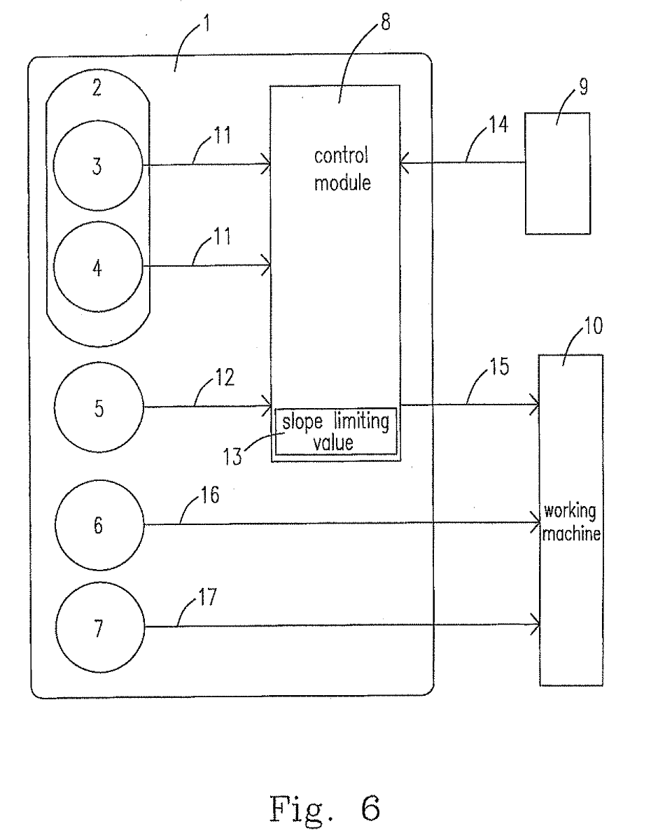

Please refer to FIG. 6, which is a diagram showing the structure of the pulse generating device according to a preferred embodiment of the present invention. Besides the foregoing torsion limiting knob 5, the axial direction determining knob 6, the multiplication parameter determining knob 7, the knob 2 and the first knob 3 and the second knob 4 therein, the pulse generating device 1 further comprises a control module 8. The control module 8 in this embodiment includes a slope limiting value 13 predetermined in the control module 8.

The first knob 3 will generate a pulse signal 11 to the control module 8 when it is twisted and actuated. The second knob 4 will generate a pulse signal 11 to the control module 8 in a frequency corresponding to a twisted angle of the second knob 4 when it is twisted and actuated.

The control module 8 is configured to receive the pulse signal 11 provided by the first knob 3 and the second knob 4, a torsion limiting value 12 provided by the torsion limiting knob 5, and a torsion value 14 provided by a driver 9 coupled to the pulse generating device 1 for triggering a working machine 10.

After receiving the pulse signal 11, the control module 8 will perform a logic operation according to the torsion limiting value 12, the torsion value 14 and the slope limiting value 13 and accordingly provide a pulse command 15 to the working machine 10. The working machine 10 will move according to the pulse command 15, an axial direction command 16 received from the axial direction determining knob 6 and a multiplication parameter command 17 received from the multiplication parameter determining knob 7.

After receiving a single pulse of the pulse signal 11 provided by the first knob 3, the control module 8 will compare the torsion value 14 with the torsion limiting value 12. If the torsion value 14 is smaller than the torsion limiting value 12, the control module 8 outputs the pulse command 15. If the torsion value 14 is larger than or is equal to the torsion limiting value 12, the control module will not output the pulse command 15.

After receiving the pulse signal 11 repeatedly provided by the second knob 4 in a frequency corresponding to a twisted angle of the second knob 4, the control module 8 will compare the torsion value 14 with the torsion limiting value 12. If the torsion value is smaller than the torsion limiting value, the control module 8 outputs the repeatedly generated pulse command 15 in the corresponding frequency.

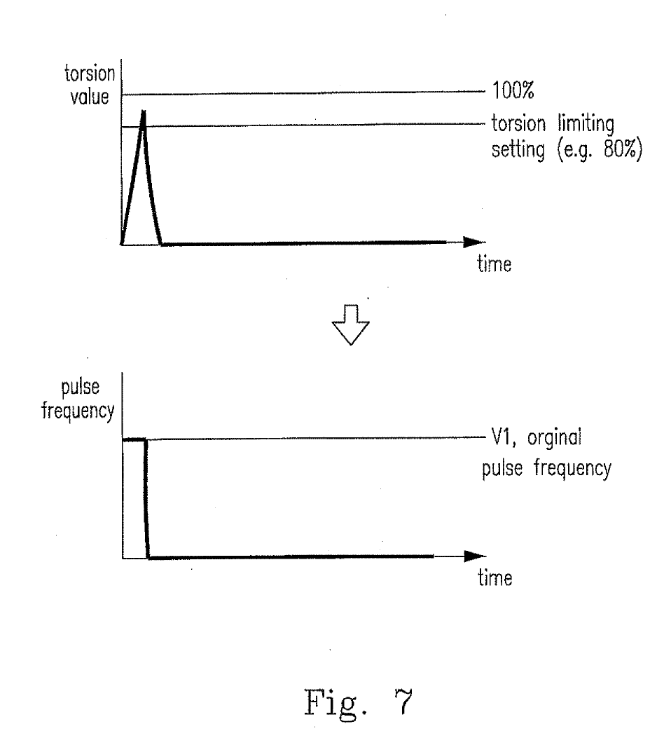

Please refer to FIG. 7, which is a diagram showing the first situation of the repeated pulse signal. After receiving the pulse signal 11 repeatedly provided by the second knob 4 in a frequency corresponding to a twisted angle of the second knob 4, the control module 8 will compare the torsion value 14 with the torsion limiting value 12. If the torsion value 14 is larger than or is equal to the torsion limiting value 12 and the slope of the torsion value 14-time curve is larger than or is equal to the slope limiting value 13, the control module 8 stops providing the pulse command 15.

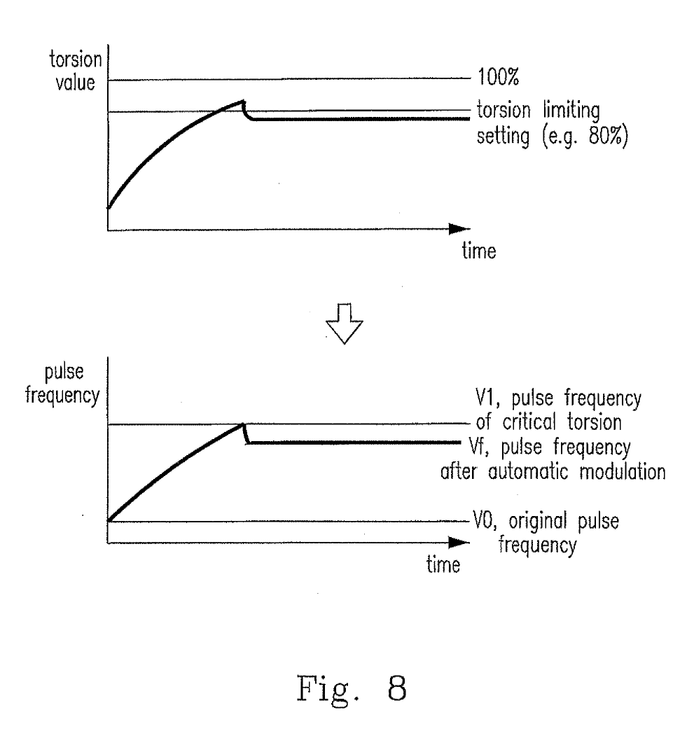

Please refer to FIG. 8, which is a diagram showing the second situation of the repeated pulse signal. After receiving the pulse signal 11 repeatedly provided by the second knob 4 in a frequency corresponding to a twisted angle of the second knob 4, the control module 8 will compare the torsion value 14 with the torsion limiting value 12. If the torsion value 14 is larger than or is equal to the torsion limiting value 12 and a slope of a torsion value 14-time curve is smaller than the slope limiting value 13, the control module 8 outputs the repeatedly generated pulse command 15 in a frequency slower than the corresponding frequency.

The foregoing preferred embodiment of the present invention includes the first knob, the second knob, the torsion limiting value and the slope limiting value for practice. However, the present invention could be independently practiced only with the first and the second knobs or only with the torsion limiting value and the slope limiting value or only with the first and the second knobs and the torsion limiting value and so on.

In conclusion, the present invention provides a pulse generating device and method. The present invention achieves the purposes of the effective move of the working machine for a long distance, the stable output of the pulse command and the better processed quality by the first and the second knobs, the torsion limiting value and the slope limiting value. Furthermore, the problems of over-cutting, over-torsion and tool broken are avoided in the present invention as well. Accordingly, the present invention can effectively solve the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A pulse generating device, comprising:
a control device receiving a pulse signal and generating a pulse command;
a first knob providing a single pulse of the pulse signal to the control device after being actuated for triggering the control device to generate a single pulse command; and
a second knob providing the pulse signal to the control device in a frequency corresponding to a twisted angle of the second knob so as to trigger the control device to repeatedly generate the pulse command.

2. A pulse generating device as claimed in claim 1, further comprising:
a torsion limiting knob setting and providing a torsion limiting value to the control device, wherein the control device is configured to receive a torsion value from a driver coupled to the pulse generating device and to compare the torsion value with the torsion limiting value, wherein:
if the torsion value is smaller than the torsion limiting value and the first knob is actuated, the control device outputs the single pulse command;
if the torsion value is smaller than the torsion limiting value and the second knob is actuated, the control device outputs the repeatedly generated pulse command in the corresponding frequency;
if the torsion value is larger than or is equal to the torsion limiting value and the first knob is actuated, the control device will not output the single pulse command; and
if the torsion value is larger than or is equal to the torsion limiting value and the second knob is actuated, the control device will not output the repeatedly generated pulse command.

3. A pulse generating device as claimed in claim 1, further comprising: a torsion limiting knob setting and providing a torsion limiting value to the control device, wherein:
if the torsion value is smaller than the torsion limiting value and the second knob is actuated, the control device outputs the repeatedly generated pulse command in the corresponding frequency; and
if the torsion value is larger than or is equal to the torsion limiting value, the control device outputs the repeatedly generated pulse command in a frequency smaller than the corresponding frequency.

4. A pulse generating device as claimed in claim 1 having a slope limiting value further comprising: a torsion limiting knob setting and providing a torsion limiting value with the control device, wherein:
if the torsion value is smaller than the torsion limiting value and the second knob is actuated, the control device outputs the repeatedly generated pulse command in the corresponding frequency;
if the torsion value is larger than or is equal to the torsion limiting value and a slope of a torsion value-time curve of a device coupled to the pulse generating device is smaller than the slope limiting value, the control device outputs the repeatedly generated pulse command in a frequency slower than the corresponding frequency; and
if the torsion value is larger than or is equal to the torsion limiting value and the slope of the torsion value-time curve is larger than or is equal to the slope limiting value, the control device will not provide the pulse commands.

5. A pulse generating device as claimed in claim 1, further comprising:
an axial direction determining unit determining an axial direction and providing an axial direction command, wherein the pulse command and the axial direction command are provided to a working machine for moving the working machine along the axial direction.

6. A pulse generating device as claimed in claim 1, further comprising:
a multiplication parameter determining unit determining a multiplication parameter for a frequency of the pulse command and providing a multiplication parameter command to a working machine for moving the working machine at a specific multiplication rate.

7. A pulse generating device as claimed in claim 1, wherein the first knob comprises a photoelectric switch, which is triggered only one time after the first knob is actuated.

8. A pulse generating device as claimed in claim 1, wherein the second knob has a variable resistance varying with the twisted angle for changing the corresponding frequency accordingly.

9. A pulse generating method for a pulse generating device, wherein the pulse generating device comprises a control device receiving a pulse signal and generating a pulse command and a knob device comprising a first knob and a second knob, comprising steps of:
(a) providing a single pulse of the pulse signal generated by manually actuating the first knob to the control device for generating a single pulse command; or
(b) repeatedly providing the pulse signal by manually actuating the second knob to the control device for repeatedly generating the pulse command.

10. A pulse generating method as claimed in claim 9, wherein the pulse generating device further comprises a torsion limiting knob and the control device is further configured to receive a torsion value, further comprising steps of:
(a) setting a torsion limiting value via the torsion limiting knob and providing the torsion limiting value to the control device; and
(b) comparing the torsion value with the torsion limiting value, wherein:
if the torsion value is smaller than the torsion limiting value and the first knob is actuated, the control device outputs the pulse command; and
if the torsion value is larger than or is equal to the torsion limiting value and the first knob is actuated, the control device will not output the pulse command.

11. A pulse generating method as claimed in claim 9, wherein the pulse generating device further comprises a torsion limiting knob and the control device is further configured to receive a torsion value, further comprising the steps of:
(a) setting a torsion limiting value via the torsion limiting knob and providing the torsion limiting value to the control device; and
(b) comparing the torsion value with the torsion limiting value, wherein:
if the torsion value is smaller than the torsion limiting value and the second knob is actuated, the control device repeatedly provides the pulse command in a frequency of receiving the pulse signal; and
if the torsion value is larger than or is equal to the torsion limiting value and the second knob is actuated, the control device will not output the pulse command.

12. A pulse generating method as claimed in claim 9, wherein the pulse generating device further comprises a torsion limiting knob and the control device is further configured to receive a torsion value, further comprising the steps of:
(a) setting a torsion limiting value via the torsion limiting knob and providing the torsion limiting value to the control device; and
(b) comparing the torsion value with the torsion limiting value, wherein:
if the torsion value is smaller than the torsion limiting value and the second knob is actuated, the control device repeatedly provides the pulse command in a first frequency of receiving the pulse signal; and
if the torsion value is larger than or is equal to the torsion limiting value and the second knob is actuated, the control device repeatedly provides the pulse command in a second frequency smaller than the first frequency of receiving the pulse signal.

13. A pulse generating method as claimed in claim 9, wherein the pulse generating device further comprises a slope limiting value and a torsion limiting knob and the control device is further configured to receive a torsion value, further comprising the steps of:
(a) setting a torsion limiting value via the torsion limiting knob and providing the torsion limiting value to the control device; and
(b) comparing the torsion value with the torsion limiting value, wherein:
if the torsion value is smaller than the torsion limiting value and the second knob is actuated, the control device repeatedly provides the pulse command in a first frequency of receiving the pulse signal;
if the torsion value is larger than or is equal to the torsion limiting value and the slope of a torsion value-time curve is smaller than the slope limiting value, the control device repeatedly provides the single pulse command in a second frequency smaller than the first frequency of receiving the pulse signals; and
if the torsion value is larger than or is equal to the torsion limiting value and the slope of the torsion value-time curve is larger than or is equal to the slope limiting value, the control device will not output the pulse command.

14. A pulse generating device, comprising:
a knob providing a pulse signal;
a control module receiving the pulse signal and generating a pulse command; and
a torsion limiting; knob setting a torsion limiting value and providing the torsion limiting value to the control module, wherein the control module compares the torsion limiting value with a received torsion value, wherein:
if the torsion value is smaller than the torsion limiting value, the control module outputs the pulse command; and
if the torsion value is larger than or is equal to the torsion limiting value, the control module performs a specific scheme.

15. A pulse generating device as claimed in claim 14, wherein the specific scheme is one of taking no action and repeatedly providing the pulse command in a first frequency smaller than a second frequency of receiving the pulse signal.

16. A pulse generating device as claimed in claim 14, wherein the control module has a slope limiting value, and the specific scheme is one of that the control module repeatedly provides the pulse command in a first frequency smaller than a second frequency of receiving the pulse signal while a slope of a torsion value-time curve is smaller than the slope limiting value, and that the control module does not output the pulse command while the slope of the torsion value-time curve is larger than or is equal to the slope limiting value.

17. A pulse generating method for a pulse generating device, wherein the pulse generating device comprises a control module, a torsion limiting knob and a pulse signal providing knob providing a pulse signal to the control module, comprising steps of:
(a) setting a torsion limiting value via the torsion limiting knob and providing the torsion limiting value to the control module; and
(b) comparing a torsion value with the torsion limiting value, wherein:
if the torsion value is smaller than the torsion limiting value, the control module generates a pulse command; and
if the torsion value is larger than or is equal to the torsion limiting value, the control module performs a specific scheme.

18. A pulse generating method as claimed in claim 17, wherein the specific scheme is one of taking no action and repeatedly providing the pulse command by the control module in a first frequency smaller than a second frequency of receiving the pulse signal.

19. A pulse generating method as claimed in claim 17, wherein the control module has a slope limiting value, and the specific scheme is one of that the control module repeatedly provides the pulse command in a first frequency smaller than a second frequency of receiving the pulse signal while a slope of a torsion value-time curve is smaller than the slope limiting value, and that the control module does not output the pulse command while the slope of the torsion value-time curve is larger than or is equal to the slope limiting value.
